(19) United States
(12) Patent Application Publication
(10) Pub. No.: US 2004/0070001 A1
(43) Pub. Date: Apr. 15, 2004

(54) LED element

(76) Inventors: Jung-Tai Lee, Taipei (TW); Der-Ming Juang, Taipei (TW)

Correspondence Address: Jung-Tai Lee & Der-Ming Juang, P.O. Box No.6-57, Chung-Ho, Taipei, 235, TW

(21) Appl. No.: 10/270,360

(22) Filed: Oct. 15, 2002

(51) Int. Cl. H01L 33/00

(52) U.S. Cl. 257/99

(57) ABSTRACT

A light emitting diode (LED) element includes a LED chip disposed on a base plate and connecting with an electrode circuit thereon via a gold wire; the LED chip is covered by a protective resin lid with fluorescer; the present invention is characterized that a colored lens is disposed on the LED chip sealed by resin with fluorescer; the colored lens is made of polycarbonate and molded through injection by mixing and adding a slight amount of ultra-violet absorbent, golden yellow chromogen, green chromogen, golden red chromogen and blue chromogen; the abovementioned combination changes the light ray generated by the LED chip into a light source with a color temperature at 2000˜5000° K.

### BACKGROUND OF THE INVENTION

1) Field of the Invention

The present invention relates to a light emitting diode (LED) element, more particularly to a light emitting element made of a LED chip and generating a light source with a color temperature of the international standard value at 2000˜5000° K.

2) Description of the Prior Art

Accordingly, a conventional light emitter assembled by a light emitting diode (LED) chip, no matter it is sealed on two LED terminals inside a transparent resin casing or, as indicated in FIG. 2, the LED chip (b) is mounted on a polycarbonate (PC) circuit board (a), connected onto an electrode circuit (a1) located on the PC circuit board (a) via a gold wire (c) and then sealed by the resin (d).

The convention LED light emitter generates red, yellow, green or white lights, or other light colors mixed by any three colors. However, none of the LED lights achieves the temperature effect of a warm hue. More particularly, a light emitting element made of a single LED chip fails to meet the preferred international color temperature standard value of 2000˜5000° K. Although the current LED is capable of saving electricity, it is unable to substitute the available tungsten light bulb, halogen light or solar light with a color temperature for a more extensive usage. Therefore, it is necessary to improve the conventional LED element.

Furthermore, in the conventional structure as indicated in FIG. 2, the resin (d) sealed on the LED chip (b) is mixed with fluorescer for increasing the brightness emitted by a certain object or for emitting light with some white color. In addition, adding various ingredients of fluorescer only generates the white lights of different degrees or lights similar to the white lights. Although said structure is capable of enhancing the generated brightness, the light ray emitted is still of a cool chromo without any color temperature. Therefore, said structure is not suitable for being applied to sites requiring the lights of warm hue and with color temperatures.

In viewing that the conventional light emitter assembled by LED chips is lack of color temperature and unable to be extensively applied thereby loosing the economic utilization value, the inventor of the present invention researched and invented an innovative LED element structure.

### SUMMARY OF THE INVENTION

The primary objective of the present invention is to provide a light emitting diode (LED) element mainly comprising a LED chip disposed on a base plate and sealed by the resin with fluorescer; a colored lens is disposed on the LED chip sealed by the resin so as to make a light ray generated by the LED element have the color temperature at 2000˜5000° K.

In order to achieve the abovementioned objective, the present invention mainly comprises the colored lens disposed on the LED chip which is guarded by a resin protective lid with fluorescer; the colored lens is made of polycarbonate plastic material (1 kg) and molded through injection by mixing and adding a slight amount of ultra-violet absorbent (1.5˜3 g), golden yellow chromogen (0.09˜0.18 g), green chromogen (0.01˜0.02 g), golden red chromogen (0.065˜0.13) and blue chromogen (0.008˜0.016 g). When using the structure assembled accordingly, the light ray of or similar to a white light generated by the LED chip which is covered by the protective lid of resin with fluorescer is further filtered by the colored lens to naturally change into a light ray having a color temperature of the international standard value of 2000˜5000° K.; that enhances the economic and industrial utilization value of a certain object.

To enable a further understanding of the structural features and the technical contents of the present invention, the brief description of the drawings below is followed by the detailed description of the preferred embodiment.

### BRIEF DESCRIPTION OF THE DRAWINGS

FIG. 1 is a cross-sectional drawing of the assembly of the present invention.

FIG. 2 is a cross-sectional drawing of the assembly of a conventional structure.

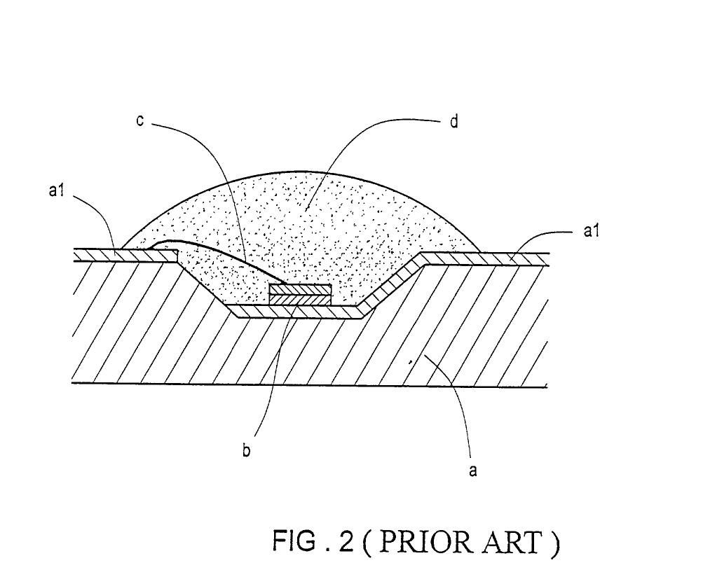

### DETAILED DESCRIPTION OF THE PREFERRED EMBODIMENTS

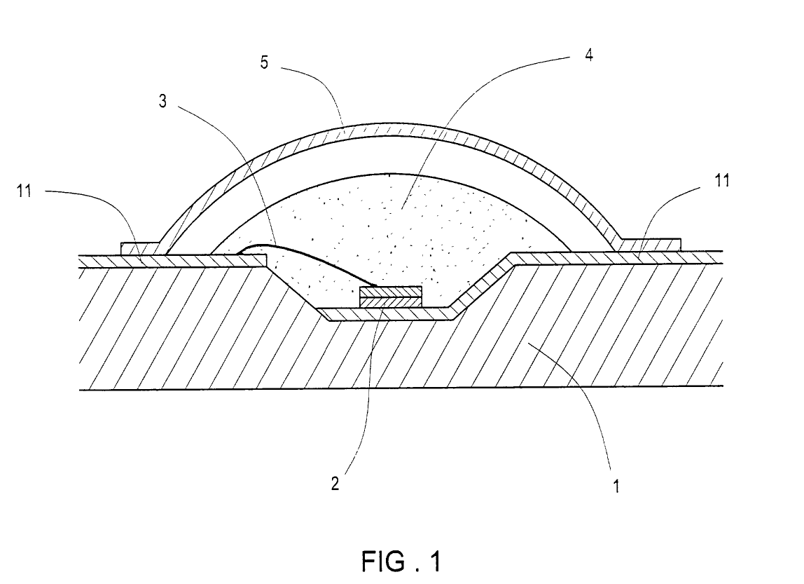

Referring to FIG. 1, the present invention comprises a light emitting diode (LED) chip (2) disposed on a base plate (1), connected onto an electrode circuit (11) on the base plate (1) via a gold wire (3) and sealed by a protective lid (4) of resin with fluorescer. The present invention is characterized that a colored lens (5) is disposed on the LED chip (2) sealed by resin with fluorescer; the colored lens is made of base polycarbonate plastic material (1 kg) and molded through injection by mixing a slight amount of ultra-violet absorbent (1.5˜3 g), golden yellow chromogen (0.09˜0.18 g), green chromogen (0.01˜0.02 g), golden red chromogen (0.065˜0.13 g) and blue chromogen (0.008˜0.016 g).

According to the abovementioned structure, the LED chip (2) is covered by the protective lid (4) of resin with fluorescer to obtain a white light or whitely light with more brightness; the colored lens (5) specially prescribed to have more orange red color is added onto the LED chip (2) for changing the white light penetrated the colored lens (5) to have a warm hue with a color temperature of the international standard value of 2000˜5000° K. That makes the present invention of a LED element overcome the shortcomings of a conventional LED element without a color temperature effect thereby extending the practical application scope and enhancing the economic effect of a certain product as well as increasing the marketing compatibility.

According to the abovementioned structure, the inventor of the present invention discovered that when the colored lens (5) of 1 kg polycarbonate plastic material is molded through injection by evenly mixing and adding 3 g ultra-violet absorbent, 0.18 g golden yellow chromogen, 0.02 g green chromogen, 0.13 g golden red chromogen and 0.016 g blue chromogen, it has a color temperature of the international standard value about 2500˜3500° K. and that is the preferred color temperature scope for a practical implement.

Furthermore, if the colored lens (5) of 1 kg polycarbonate plastic material is molded through injection by evenly mixing and adding 1.5 g ultra-violet absorbent, 0.09 g golden yellow chromogen, 0.01 g green chromogen, 0.065 g golden red chromogen and 0.08 g blue chromogen, it has a color temperature of the international standard value about 4000° K. With a proper adjustment of the amount of the additives, the color temperature effect of 2000˜5000° K. can be achieved. That equivalent variation is within the patent scope of the present invention.

It is of course to be understood that the embodiment described herein is merely illustrative of the principles of the invention and that a wide variety of modifications thereto may be effected by persons skilled in the art without departing from the spirit and scope of the invention as set forth in the following claims.

1. A light emitting diode (LED) element comprising a LED chip disposed on a base plate, connected to an electrode circuit on a base plate via a gold wire and covered by a protective lid of resin with fluorescer is characterized that a colored lens is mounted on the LED chip for making the light ray emitted therefrom has a color temperature at 2000˜5000° K.

2. The present invention of a light emitting diode (LED) element according to claim 1, wherein the colored lens of 1 kg polycarbonate plastic material is molded through injection by evenly mixing and adding (1.5˜3 g) ultra-violet absorbent, (0.09˜0.18 g) golden yellow chromogen, (0.01˜0.02 g) green chromogen, (0.065˜0.13 g) golden red chromogen and (0.008˜0.016 g) blue chromogen.
